(19) United States
(12) Patent Application Publication
(10) Pub. No.: US 2007/0047205 A1
(43) Pub. Date: Mar. 1, 2007

(54) Coolant injection process and fixture for the same

(76) Inventors: Wei-Chih Lin, Taichung City (TW); Shih-Min Wu, Yilan City (TW); Chi-Neng Mo, Jhongli City (TW)

Correspondence Address: J.C. Patents, Inc.;Suite 250, 4 Venture, Irvine, CA, 92618, US

(21) Appl. No.: 11/222,050

(22) Filed: Sep. 7, 2005

(30) Foreign Application Priority Data
Aug. 24, 2005 (TW) 94128882

(51) Int. Cl. H05K 7/20

(52) U.S. Cl. 361/700

(57) ABSTRACT

A coolant injection process suitable for injecting a coolant into a projection tube having a coolant injection entrance is provided. First, a sealing element is arranged at the coolant injection entrance. Then, the coolant is injected into the projection tube through the coolant injection entrance under sub-atmospheric, wherein the level of the coolant is kept higher than the coolant injection entrance. Next, the coolant injection entrance is sealed by the sealing element under sub-atmospheric. Then, the coolant remaining outside the coolant injection entrance is removed. Moreover, a fixture for the coolant injection process is provided for injecting the coolant into the projection tube. The coolant injection process and the fixture for the same can reduce take time of the process and improve reliability of the projection tube.

### CROSS-REFERENCE TO RELATED APPLICATION

This application claims the priority benefit of Taiwan application serial no. 94128882, filed on Aug. 24, 2005. All disclosure of the Taiwan application is incorporated herein by reference.

### BACKGROUND OF THE INVENTION

1. Field of the Invention

The present invention generally relates to an injection process and a fixture for the same. More particularly, the present invention relates to a coolant injection process and a fixture for the same.

2. Description of Related Art

Being an important device of a cathode ray tube (CRT) display, the projection tube will be degraded or damaged due to the heat accumulated in operation. In order to resolve the problem mentioned above, a coolant is injected into the projection tube for removing the heat by means of conduction and convection.

A conventional coolant injection process is described as follows. First, a sub-atmospheric environment formed by a vacuum pump is provided. Then, a projection tube having an opening is disposed in the sub-atmospheric environment, and a coolant is injected into the projection tube through the opening, wherein the quantity of the coolant is substantially equal to the capacity of the projection. Next, the air remain in the coolant injected into the projection tube is removed. After that, the sub-atmospheric environment is removed, and an oil seal ring is disposed at the opening manually.

Moreover, since the practical quantity of the coolant injected into the projection tube is usually less than an expected quantity, a manual refilling step is performed to complement the lack of the coolant after disposing the oil seal ring at the opening. Then, the opening is sealed by the oil seal ring for isolating the coolant within the projection tube from the external environment. However, the additional refilling step according to the conventional coolant injection process described above leads to the consumption of processing time and cost.

In addition, the step of disposing the oil seal is performed under atmospheric, thus the air may be sealed into the projection tube at the same time and forms bubbles in the projection tube. The bubbles will deteriorate the optical property of the projection tube and the effect of heat diffusion of the coolant and thus diminishes the reliability of the projection tube.

### SUMMARY OF THE INVENTION

Accordingly, the present invention is directed to a coolant injection process and a fixture used in the process, which are capable of substantially reducing the processing time and improving the reliability of the projection tube.

The present invention provides a coolant injection process, which is suitable for injecting a coolant into a projection tube having a coolant injection entrance. First, a sealing element is arranged at the coolant injection entrance. Then, the coolant is injected into the projection tube through the coolant injection entrance under sub-atmospheric, wherein the level of the coolant is kept higher than the coolant injection entrance. Next, the coolant injection entrance is sealed by the sealing element under sub-atmospheric. Then, the coolant remaining outside the coolant injection entrance is removed.

According to an embodiment of the present invention, wherein the method for arranging the sealing element comprises leaning one side of the sealing element against the coolant injection entrance.

According to an embodiment of the present invention, the sealing element is arranged at the coolant injection entrance by a locating device.

For example, the locating device may comprises a rod, which supports another side of the sealing element in the step of arranging the sealing element and is removed to release the sealing element into the coolant injection entrance in the step of sealing the coolant injection entrance.

In another case, the locating device may comprises a robot, which clamps another side of the sealing element in the step of arranging the sealing element and releases the sealing element into the coolant injection entrance in the step of sealing the coolant injection entrance.

According to an embodiment of the present invention, the coolant injection process further comprises pressing the sealing element by the locating device as removing the coolant remaining outside the coolant injection entrance.

The present invention also provides a coolant injection fixture, which is suitable for a coolant injection process of a projection tube having a coolant injection entrance. The coolant injection fixture comprises: a vacuum chamber, providing a sub-atmospheric environment; an injection pipe, disposed in the vacuum chamber for providing a coolant into the projection tube under sub-atmospheric; and a locating device, disposed in the vacuum chamber for arranging a sealing element at the coolant injection entrance.

According to an embodiment of the present invention, the vacuum chamber is disposed over the coolant injection entrance.

According to an embodiment of the present invention, the projection tube is disposed in the vacuum chamber.

According to an embodiment of the present invention, the coolant injection fixture further comprises a suction pipe for removing the coolant remaining outside the coolant injection entrance after the coolant injection entrance is sealed.

According to an embodiment of the present invention, the locating device comprises a rod for supporting one side of the sealing element to arrange the sealing element at the coolant injection entrance at an angle.

According to an embodiment of the present invention, the locating device comprises a robot for clamping one side of the sealing element to arrange the sealing element at the coolant injection entrance at an angle.

According to an embodiment of the present invention, the sealing element comprises an oil seal ring.

Accordingly, the coolant injection process and the fixture mentioned above inject the coolant into the projection tube and seal the coolant injection entrance of the projection tube under sub-atmospheric. Therefore, the bubbles within the projection tube can be drastically reduced, and thus the processing yield and the reliability of the projection tube can be improved.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A through 1B schematically illustrate a coolant injection process according to one embodiment of the present invention.

FIG. 2 schematically illustrates a coolant injection process using another kind of coolant injection fixture according to one embodiment of the present invention.

FIG. 3 schematically illustrates another kind of locating device according to the present invention.

FIG. 4 further schematically illustrates another kind of locating device according to the present invention.

### DESCRIPTION OF THE EMBODIMENTS

Reference will now be made in detail to the present embodiments of the invention, examples of which are illustrated in the accompanying drawings. Wherever possible, the same reference numbers are used in the drawings and the description to refer to the same or like parts.

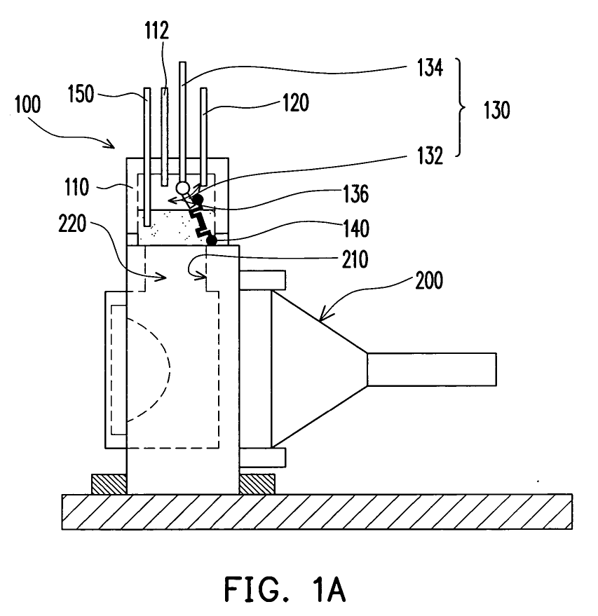

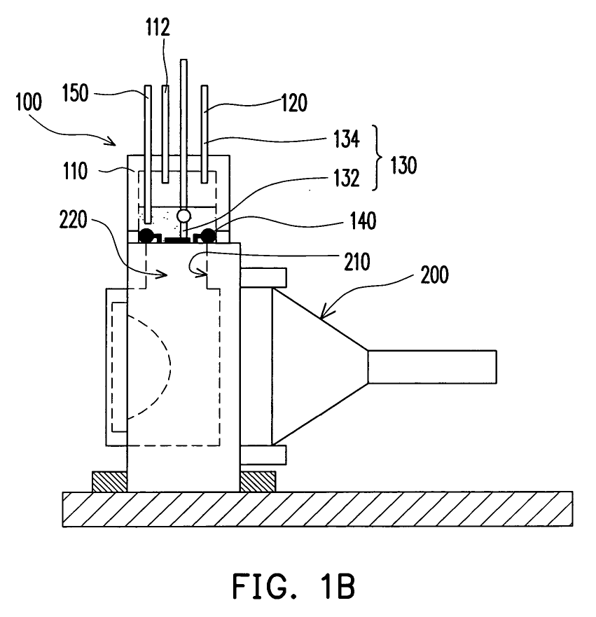

FIGS. 1A through 1B schematically illustrate a coolant injection process according to one embodiment of the present invention. Referring to 1A, the projection tube 200 has a coolant injection entrance 210 and a chamber 220, wherein the coolant injection entrance 210 and the chamber 220 are connected to each other. In addition, a coolant injection fixture 100 comprising a cover 110, an injection pipe 120, and a locating device 130 is provided. Wherein, the cover 110 is disposed over the coolant injection entrance 210 and connected to a vacuum pump through a pipe 112 to form a vacuum environment in the cover 110 and keep the chamber 220 under sub-atmospheric. In addition, the injection pipe 120 is disposed in the cover 110 for injecting a coolant into the chamber 220 under sub-atmospheric.

A locating device 130 is disposed in the cover 110, wherein the locating device 130 and the cover 110 may be connected through an airtight joint or a sealant. In the embodiment, the locating device 130 may be a linkage comprising rods 132 and 134, wherein one end of the rod 132 is pivotally connected to one end of the rod 134, and the other end of the rod 132 supports a sealing element 140 to arrange the sealing element 140 at the coolant injection entrance 210. The sealing element 140 may be an oil seal ring.

Specifically, referring to FIG. 1A, the present invention arranges the sealing element 140 at the coolant injection entrance 210 at an angle, wherein one side of the sealing element 140 is leaned against the coolant injection entrance 210, and the other side of the sealing element 140 is supported by the rod 132. Then, the cover is disposed over the coolant injection entrance 210 for providing a sub-atmospheric environment. The vacuum chamber formed in the cover 110 is connected to the chamber 220 within the projection tube 200 through the coolant injection entrance 210, thus the chamber 220 is kept under sub-atmospheric by the vacuum pump. Next, the coolant is injected into the chamber 220 by the injection pipe 120 in the coolant injection fixture 100, wherein the level of the coolant is kept higher than the coolant injection entrance 210.

Then, referring to FIG. 1B, the coolant injection entrance 210 is sealed by the sealing element 140 under sub-atmospheric. In the embodiment, the rod 132 is removed in the manner of rotating the rod 132 along a direction 136 by using the pivotally connecting portions of the rods 132 and 134 as a pivot. Thus, the sealing element 140 is released and embedded into the coolant injection entrance 210, and the coolant is sealed within the projection 200. After that, the coolant remaining outside the coolant injection entrance 210 is removed by the suction pipe 150. Wherein, the rod 132 may press on the sealing element 140 to prevent the sealing element 140 from being attracted as removing the coolant by the suction pipe 150.

Since the level of the coolant is kept higher than the coolant injection entrance 210 as injecting the coolant, and the steps of injecting the coolant and sealing the coolant injection entrance 210 are performed under sub-atmospheric, the problem of remaining bubbles in the projection tube 200 can be resolved for improving the processing yield, and the frequency of manual refilling can be reduced for saving the take time.

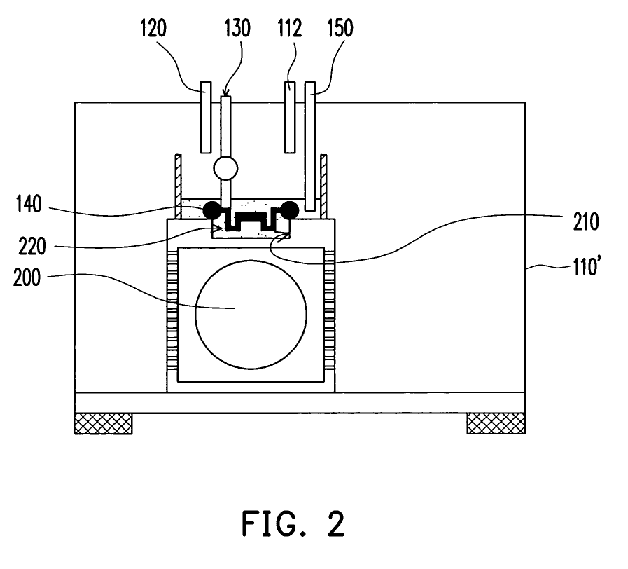

FIG. 2 schematically illustrates a coolant injection process using another kind of coolant injection fixture according to one embodiment of the present invention. Expect disposing the cover over the coolant injection entrance 210, the present invention can also provide a box 110′ for containing the projection tube 200 to form a vacuum chamber by a vacuum pump. Since the steps of the coolant injection process by using the coolant injection fixture is similar to the embodiment mentioned above, detailed description is not repeated.

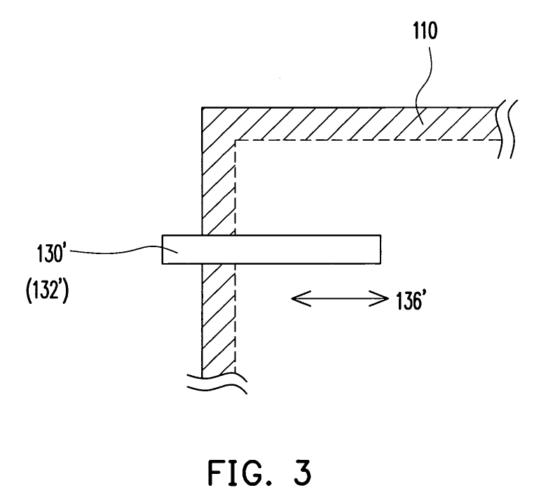

It should be noted that the present invention provides other types of the locating device expect the linkage mentioned above. For example, FIG. 3 schematically illustrates another kind of locating device according to the present invention. Referring to FIGS. 2 and 3, the locating device 130′ is a rod 132′ disposed on the sidewall of the cover 110 and makes a transversely motion along direction 136′ for performing the action of arranging the sealing element 140 or releasing the sealing element 140 into the coolant injection entrance 210. In addition, the wherein the rod 132′ and the cover 110 may be connected through an airtight joint or a sealant to preserve degree of vacuum in the cover 110.

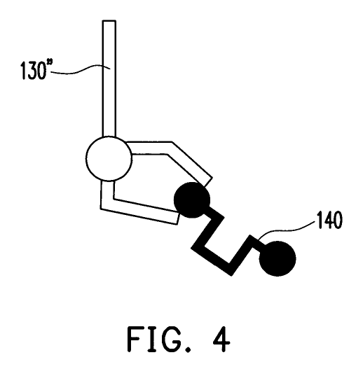

FIG. 4 further schematically illustrates another kind of locating device according to the present invention. Referring to FIGS. 2 and 4, the locating device 130″ is a robot for clamping one side of the sealing element 140 to arrange the sealing element 140 at the coolant injection entrance 132. In addition, the sealing element 140 is embedded into the coolant injection entrance 132 as releasing the clamping of the locating device 130″. In similar, the locating device 130″ may press on the sealing element 140 as removing the coolant remaining outside the sealing element 140 by the suction pipe 150.

It should be noted that the locating device according to the present invention is not limited to the rods or the robot mentioned above, and other devices or mechanisms capable of providing the same function is adoptable.

In summary, by the coolant injection process and the fixture for the same, the coolant is injected and sealed into the projection tube under sub-atmospheric for reducing the bubbles in the projection tube. Therefore, the processing yield and the reliability of the projection tube can be improved. In addition, the frequency of refilling the coolant manually can be reduced to save the processing time.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A coolant injection process suitable for injecting a coolant into a projection tube having a coolant injection entrance, comprising:
arranging a sealing element at the coolant injection entrance;
injecting the coolant into the projection tube through the coolant injection entrance under sub-atmospheric and keeping the level of the coolant higher than the coolant injection entrance;
sealing the coolant injection entrance by the sealing element under sub-atmospheric; and
removing the coolant remaining outside the coolant injection entrance.

2. The coolant injection process according to claim 1, wherein the method for arranging the sealing element comprises leaning one side of the sealing element against the coolant injection entrance.

3. The coolant injection process according to claim 2, wherein the sealing element is arranged at the coolant injection entrance by a locating device.

4. The coolant injection process according to claim 3, wherein the locating device comprises a rod, which supports another side of the sealing element in the step of arranging the sealing element and is removed to release the sealing element into the coolant injection entrance in the step of sealing the coolant injection entrance.

5. The coolant injection process according to claim 3, wherein the locating device comprises a robot, which clamps another side of the sealing element in the step of arranging the sealing element and releases the sealing element into the coolant injection entrance in the step of sealing the coolant injection entrance.

6. The coolant injection process according to claim 3, further comprising pressing the sealing element by the locating device as removing the coolant remaining outside the coolant injection entrance.

7. A coolant injection fixture suitable for a coolant injection process of a projection tube having a coolant injection entrance, comprising:
a vacuum chamber, providing a sub-atmospheric environment;
an injection pipe, disposed in the vacuum chamber for providing a coolant into the projection tube under sub-atmospheric; and
a locating device, disposed in the vacuum chamber for arranging a sealing element at the coolant injection entrance.

8. The coolant injection fixture according to claim 7, wherein the vacuum chamber is disposed over the coolant injection entrance.

9. The coolant injection fixture according to claim 7, wherein the projection tube is disposed in the vacuum chamber.

10. The coolant injection fixture according to claim 7, further comprising a suction pipe for removing the coolant remaining outside the coolant injection entrance after the coolant injection entrance is sealed.

11. The coolant injection fixture according to claim 7, wherein the locating device comprises a rod for supporting one side of the sealing element to arrange the sealing element at the coolant injection entrance at an angle.

12. The coolant injection fixture according to claim 7, wherein the locating device comprises a robot for clamping one side of the sealing element to arrange the sealing element at the coolant injection entrance at an angle.

13. The coolant injection fixture according to claim 7, wherein the sealing element comprises an oil seal ring.
